(19) United States
(12) Patent Application Publication
(10) Pub. No.: US 2026/0293763 A1
(43) Pub. Date: Sep. 24, 2026

(54) SEMICONDUCTOR DEVICES, MANUFACTURING METHODS THEREOF, AND MEMORY SYSTEMS

(71) Applicant: Yangtze Memory Technologies Co., Ltd., Wuhan (CN)

(72) Inventors: Xu Hou, Wuhan (CN); Bin Liao, Wuhan (CN); Yu Wang, Wuhan (CN)

(21) Appl. No.: 19/370,320

(22) Filed: Oct. 27, 2025

(30) Foreign Application Priority Data
Mar. 18, 2025 (CN) 202510322762.1

(51) Int. Cl. H01L 25/18; H01L 21/768; H01L 23/00; H01L 23/522; H01L 23/528; H10B 80/00; H10D 80/30

(52) U.S. Cl. CPC H10W 90/00; H10B 80/00; H10D 80/30; H10W 20/056; H10W 20/076; H10W 20/42; H10W 20/43; H10W 20/435; H10W 80/312; H10W 80/327; H10W 90/26; H10W 90/297; H10W 90/792

(57) ABSTRACT

Examples of the present disclosure provide a semiconductor device, a manufacturing method thereof, and a memory system, where the semiconductor device includes: a first semiconductor structure including a first bonding layer, a peripheral circuit layer including a logic circuit, and an interconnection layer; a second semiconductor structure including a memory array layer including DRAM memory cells and a second bonding layer; the second bonding layer being bonded to the first bonding layer; where the first semiconductor structure further includes: a first interconnection structure between the logic circuit and the first bonding layer; a contact structure penetrating through a semiconductor layer where the logic circuit is located; and a second interconnection structure and a pad in the interconnection layer; the logic circuit being connected to the pad through the first interconnection structure, the contact structure, and the second interconnection structure.

### CROSS-REFERENCE TO RELATED APPLICATIONS

This application claims priority to and the benefit of Chinese Patent Application 202510322762.1, filed on Mar. 18, 2025, which is hereby incorporated by reference in its entirety.

### TECHNICAL FIELD

The present disclosure relates to the field of semiconductor technology, and in particular, to semiconductor devices, manufacturing methods thereof, and memory systems.

### BACKGROUND

A semiconductor device, such as a dynamic random access memory (DRAM), is one of the most important access components in an electronic system, and uses a transistor (T) and a capacitor (C) to form a 1T1C structure as a memory cell. Such a 1T1C structure enables dynamic random access memory to have higher integration and lower cost, and holds an irreplaceable position in computer access devices.

### BRIEF DESCRIPTION OF THE DRAWINGS

FIG. 1 is a schematic block diagram of the composition of an example electronic device according to an example of the present disclosure;

FIG. 2 is a schematic diagram of the composition of an example electronic device according to an example of the present disclosure;

FIG. 3 is a schematic block diagram of the composition of an example solid state disk according to an example of the present disclosure;

FIG. 4 is a schematic block diagram of the composition of an example memory according to an example of the present disclosure;

FIG. 5 is a schematic structural diagram of a dynamic random access memory according to an example of the present disclosure;

FIG. 6 is a schematic top view of bonding contacts and a metal layer according to an example of the present disclosure;

FIG. 7 is a schematic cross-sectional view of a semiconductor device according to an example of the present disclosure;

FIG. 8 is a schematic perspective view of a semiconductor device according to an example of the present disclosure;

FIG. 9 is a cross-sectional view of the semiconductor device shown in FIG. 8 in an XZ plane;

FIG. 10 is a schematic top view of a first metal layer on a back surface of a first semiconductor structure in an XY plane according to an example of the present disclosure;

FIG. 11 is a schematic flowchart of a manufacturing method of a semiconductor device according to an example of the present disclosure;

FIG. 12 to FIG. 14 are schematic diagrams of a manufacturing process of a semiconductor structure according to an example of the present disclosure.

In the above drawings, which are not necessarily drawn to scale, like reference numerals may depict similar components in different views. Like reference numbers with different letter suffixes may represent different examples of similar components. The drawings generally illustrate various examples discussed herein by way of example and not limitation.

### DETAILED DESCRIPTION

With the rapid development of semiconductor technology, dynamic random access memory is rapidly developing towards high-density and high-quality direction. Example implementations disclosed in the present disclosure will be described in more detail below with reference to the drawings. Although example implementations of the present disclosure are shown in the drawings, it is to be understood that the present disclosure may be implemented in various forms and should not be limited by the implementations set forth here. Rather, these implementations are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual example are described here, and well-known functions and structures are not described in detail.

In the drawings, the sizes of layers, regions, elements, and their relative sizes may be exaggerated for clarity. Like reference numbers refer to like elements throughout.

It should be understood that spatial relation terms such as “beneath,” “below,” “lower,” “under”, “above,” “upper,” etc., may be used here for ease of description to describe the relationship between one element or feature and other elements or features shown in the figures. It should be appreciated that in addition to the orientations shown in the figures, the spatial relation terms are intended to also comprise different orientations of the devices in use and operation. For example, if the devices in the figures are flipped, then the devices described as being “below” or “under” or “beneath” other elements or features will be oriented “on” other elements or features. Thus, the example terms “below” and “under” may comprise both upper and lower orientations. The devices may be otherwise oriented (rotated 90 degrees or other orientations) and the spatial description terminology used here is interpreted accordingly.

A term used here is for the purpose of describing a particular example only and is not to be considered as limitation of the present disclosure. As used here, the singular forms “a”, “an” and “said/the” are intended to comprise the plural forms as well, unless the context clearly dictates otherwise. It should also be understood that the terms “consist of” and/or “comprise”, when used in this description, identify the presence of stated features, integers, steps, operations, elements and/or parts, but do not exclude the presence or addition of one or more other features, integers, steps, operations, elements, parts and/or groups. As used here, the term “and/or” comprises any and all combinations of the associated listed items.

For a more detailed understanding of the features and technical contents of the examples of the present disclosure, the implementations of the examples of the present disclosure are described in detail below with reference to the drawings, and the drawings are for illustrative purposes only and are not intended to limit the examples of the present disclosure.

The semiconductor devices related to the examples of the present disclosure will be used in subsequent processes to form at least a portion of the final device structure. Here, the final device may comprise a memory comprising, but is not limited to, a dynamic random access memory (DRAM), and the following takes dynamic random access memory as an example to illustrate. However, it should be noted that the following description of the dynamic random access memory is only used to illustrate the present disclosure, and is not intended to limit the scope of the present disclosure.

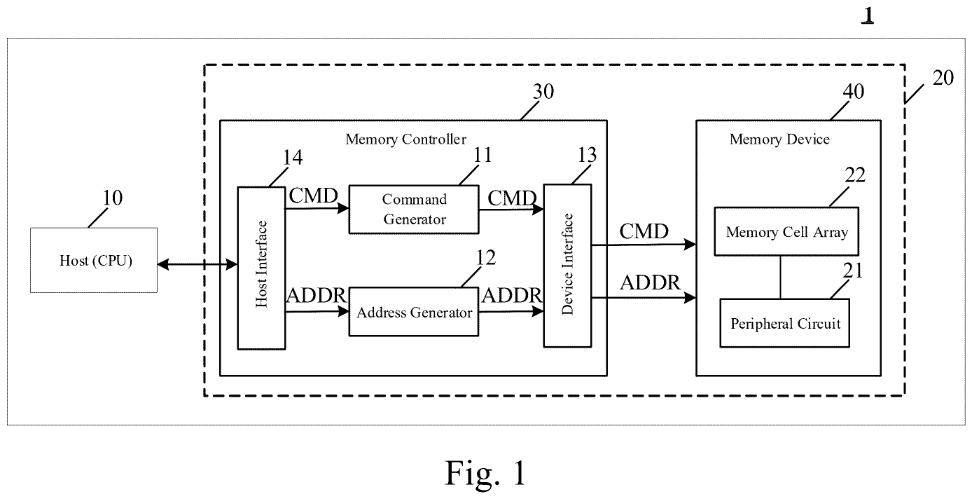

FIG. 1 illustrates a schematic block diagram of the composition of an example electronic device according to an example of the present disclosure. The electronic device 1 may be a mobile phone, a desktop computer, a laptop computer, a tablet computer, a vehicle computer, a game console, a printer, a pointing device, a wearable electronic device, a smart sensor, a virtual reality (VR) device, an augmented reality (AR) device, or any other suitable electronic device having a storage there. As shown in FIG. 1, the electronic device 1 may comprise a host 10 and a memory system 20 comprising a memory controller 30 and one or more memory devices 40. The host 10 may be a processor (for example, a central processing unit (CPU) or a graphics processing unit (GPU)) of the electronic device. The host 10 may be configured to send or receive data to or from the memory device 40. The memory controller 30 is coupled to the memory device 40 and the host 10 and is configured to control the memory device 40. The memory controller 30 may manage data stored in the memory device 40 and communicate with the host 10.

The memory controller 30 may be configured to control operations of the memory device 40, such as read, erase, write, and refresh operations. In some implementations, the memory controller 30 is further configured to process error correction code (ECC) regarding data read from or written to the memory device 40. Memory controller 30 may also perform any other suitable function, such as formatting memory device 40.

In some examples, the memory controller 30 and the one or more memory devices 40 may each be integrated into various types of electronic devices, for example, the memory controller 30 may be integrated into a northbridge chipset of a motherboard of a computer or integrated directly into a CPU of a computer; and multiple memory devices 40 can be integrated into a memory module. That is, the memory system 20 may be implemented and packaged into different types of terminal electronics.

The memory controller 30 may send/receive data to/from the host 10, and may send a command CMD and an address ADDR to the memory device 40. Memory controller 30 may comprise command generator 11, address generator 12, device interface 13, and host interface 14. The host interface 14 may receive the command CMD and the address ADDR from the host 10, the command generator 11 may generate an access command, etc., by decoding the command CMD received from the host 10, and may provide the access command to the memory device 40 through the device interface 13. The access command may be a signal indicating that the memory device 40 writes or reads data by accessing a row of the memory cell array 22 corresponding to the address ADDR. The address generator 12 in the memory controller 30 may generate row addresses and column addresses to be accessed in the memory cell array 22 by decoding the address ADDR received from the host interface 14. Further, the memory device 40 may generate addresses of memory banks to be accessed when the memory cell array 22 comprises multiple memory banks.

Further, the memory controller 30 may control memory operations such as write and read by providing various signals to the memory device 40 via the device interface 13. For example, the memory controller 30 may provide a write command to the memory device 40. The write command is configured to instruct the memory device 40 to perform a write operation to store data into the memory device 40.

In some examples, the memory device 40 comprises a memory cell array 22 and a peripheral circuit 21. Herein, the memory cell array 22 comprises a plurality of memory banks, each memory bank comprises a plurality of memory blocks, each memory block comprises a plurality of memory cell rows and a plurality of memory cell rows, each memory cell row is coupled with a corresponding word line, and each memory cell column is coupled with a corresponding bit line. The peripheral circuit 21 may write data to or read data from the memory cell array 22 based on the command CMD and address ADDR received from the memory controller 30, or may provide control signals CTRL for refreshing memory cells comprised in the memory cell array 22 to the row decoding circuit and the column decoding circuit. In other words, the peripheral circuit 21 may perform all operations to process data in the memory cell array 22. The peripheral circuit 21 may comprise: a control circuit corresponding to each memory bank, for example, a sense amplification circuit and a word-line driver (WLD), etc., a control circuit corresponding to each memory bank, for example, a row decoding circuit, a column decoding circuit, etc., and a control circuit corresponding to all memory banks, for example, a command buffer, a command decoder, an address buffer, an input/output buffer, a mode register, etc.

The memory device 40 may be a random access memory (RAM), such as a dynamic random access memory (DRAM), synchronous DRAM (SDRAM), static RAM (SRAM), double data rate SDRAM (DDR SDRAM), DDR2 SDRAM, DDR3 SDRAM, phase-change RAM (PRAM), magnetic RAM (MRAM), resistive RAM (RRAM), NAND type memory, or the like. The following only takes DRAM as an example to illustrate.

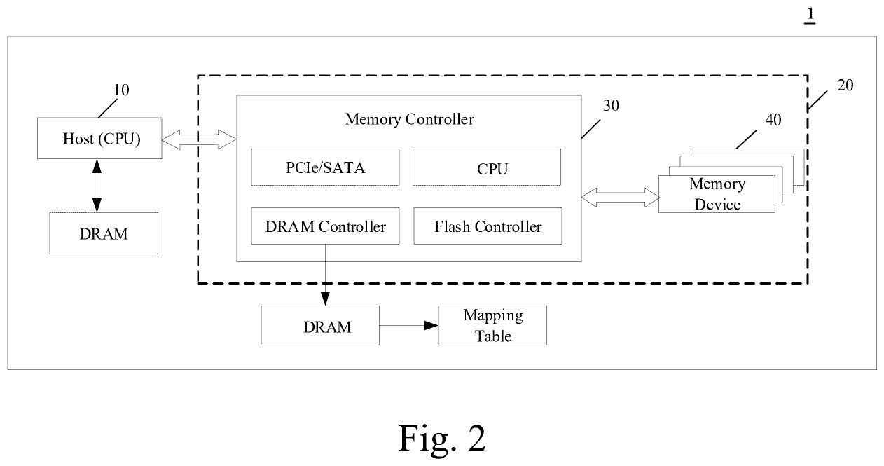

FIG. 2 is a schematic diagram of the composition of an example electronic device according to an example of the present disclosure. In some examples, the DRAM may belong to a structure external to the memory system 20, and may be directly connected to the host 10 to serve as a main memory when the host 10 runs. The DRAM may also be connected to the memory system 20 to serve as a buffer memory. In some other examples, the DRAM may also be part of a controller in the memory system 20, such as a DRAM controller, for controlling the memory device 40 to perform operations such as write and read. In some other examples, the plurality of DRAM stack settings may be applied to a high bandwidth memory (HBM) architecture to serve as a storage medium.

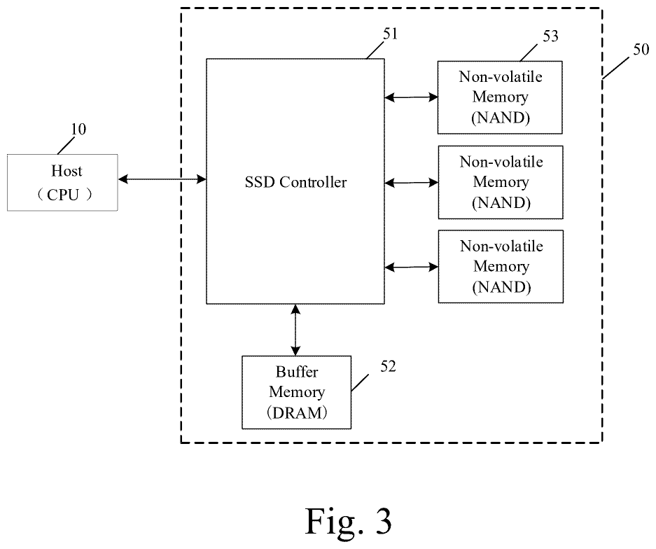

For example, referring to FIG. 3, FIG. 3 is a schematic block diagram of the composition of an example solid state drive (SSD) according to an example of the present disclosure. Here, the SSD may be understood as one of the memory systems 20 in FIG. 1 and FIG. 2, and in this example, the DRAM may be used as a buffer memory.

As shown in FIG. 3, the SSD 50 may comprise an SSD controller 51, a buffer memory 52, and a non-volatile memory 53. The SSD controller 51 may provide a physical connection between host 10 and SSD 50. That is, the SSD controller 51 may provide an interface between host 10 and SSD 50 in accordance with the bus format of host 10. The SSD controller 51 may decode instructions provided from the host 10. The SSD controller 51 may access the non-volatile memory 53 based on the result of the decoding. The buffer memory 52 may temporarily store write data provided from the host 10, or data read from the non-volatile memory 53. When the host 10 issues a read request, if the data present in the non-volatile memory 53 is cached, the buffer memory 52 may support the caching functionality for providing cached data directly to the host. The data transfer rate through bus format (e.g., SATA or SAS) of the host is much higher than the data transfer rate of the memory channel of the SSD 50. That is, when interface speed of the host is significantly high, performance degradation due to speed differences may be minimized by providing the buffer memory 52 with high capacity. In addition, the buffer memory 52 may store an address mapping table of the non-volatile memory 53. The buffer memory 52 may comprise, but is not limited to, DRAM. Non-volatile memory 53 may be provided as a storage medium for SSD 50. The non-volatile memory 53 may comprise, but is not limited to, a NAND-type memory.

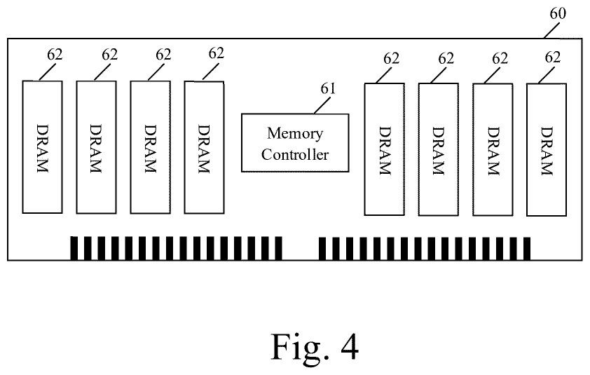

FIG. 4 is a schematic block diagram of the composition of an example memory according to an example of the present disclosure. Here, the memory may be understood as one of the memory systems 20 in FIG. 1 and FIG. 2, and in this example, the DRAM may be used as a storage medium.

As shown in FIG. 4, the memory 60 can be easily attached or mounted to or detached from the electronic device 1 through the illustrated interface. The memory 60 may comprise a plurality of volatile memories 62 (e.g., DRAM) and a memory controller 61. The memory 60 may be configured to write data, store data, obtain (or read) data, and/or erase data under a controller of a processor of a computer. In some examples, the memory controller 61 may communicate with the DRAM using at least one of communication protocols or technology standards commonly associated with, for example, a dual in-line memory module (DIMM), a registered DIMM (RDIMM), a low load DIMM (LRDIMM), an unregistered DIMM (UDIMM), or the like.

It should be noted that both the buffer memory 52 in FIG. 3 and the volatile memory 62 in FIG. 4 are application scenarios of the memory device 40 in FIG. 1 or FIG. 2.

With the development of dynamic random access memory technology, the size of DRAM memory cells is smaller and smaller, and its array architecture is from 8F² to 6F² to 4F² ; in addition, based on the requirements of dynamic random access memory on ions and leakage current, the architecture of the memory is from a planar array transistor to a recess gate array transistor, and from the recess gate array transistor to a buried channel array transistor, and then from the buried channel array transistor to a vertical channel array transistor.

In some examples of the present disclosure, whether a planar transistor or a buried transistor, the dynamic random access memory is composed of a plurality of DRAM memory cells, each DRAM memory cell is composed of a transistor and a capacitor controlled by the transistor, that is, the dynamic random access memory (DRAM) comprises a architecture of one transistor and one capacitor (1T1C); and the main function principle of the architecture is to use the amount of charges stored in the capacitor to represent whether one binary bit is 1 or 0.

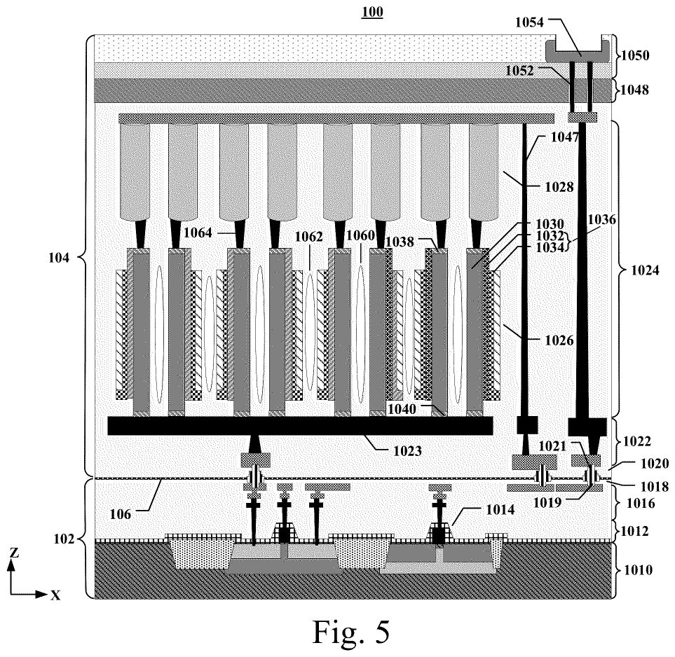

One of the architectures of the dynamic random access memory is described in detail below with reference to FIG. 5. Before introducing the semiconductor device shown in FIG. 5, various directions that may be used in the following description are first defined. The extension direction of the semiconductor body is defined as a first direction (e.g., the Z-axis direction). A second direction (e.g., the X-axis direction) and a third direction (e.g., the Y-axis direction) that intersect with each other are defined in a plane perpendicular to the Z-axis direction. In some examples, the X-axis direction, the Y-axis direction, and the Z-axis direction may be perpendicular to each other.

Referring to FIG. 5, FIG. 5 is a cross-sectional view of a three-dimensional (3D) dynamic random access memory 100 comprising a vertical transistor according to an example of the present disclosure; as shown in FIG. 5, the dynamic random access memory 100 comprises a first semiconductor structure 102 and a second semiconductor structure 104 stacked over the first semiconductor structure 102 along the Z-axis direction, and the first semiconductor structure 102 and the second semiconductor structure 104 are connected by a bonding interface 106; and the first semiconductor structure 102 and the second semiconductor structure 104 may be connected in a hybrid bonding manner. In some examples, the second semiconductor structure 104 may be bonded on top of the first semiconductor structure 102 in a face-to-face manner at the bonding interface 106.

The first semiconductor structure 102 may comprise a first substrate 1010, a peripheral circuit 1012 located on one side of the first substrate 1010, and a first interconnection layer 1016 located on one side of the peripheral circuit 1012 away from the first substrate 1010, and the first interconnection layer 1016 is configured to transmit an electrical signal of the peripheral circuit 1012. The peripheral circuit 1012 may comprise a plurality of transistors 1014. In some examples, trench isolation (e.g., shallow trench isolation (STI)) and doped regions (e.g., well, source, and drain of transistor 1014) may also be formed on or in the first substrate 1010.

The first semiconductor structure 102 may further comprise a first bonding layer 1018 at the bonding interface 106 and on one side of the first interconnection layer 1016 away from the peripheral circuit 1012. The first bonding layer 1018 may comprise a plurality of first bonding contacts 1019 and a dielectric electrically isolating the first bonding contacts 1019. The first bonding contacts 1019 in the first bonding layer 1018 and the surrounding dielectric may be used for hybrid bonding. Correspondingly, the second semiconductor structure 104 may also comprise a second bonding layer 1020 at the bonding interface 106 and located on one side of the first bonding layer 1018 away from the first interconnection layer 1016. The second bonding layer 1020 may comprise a plurality of second bonding contacts 1021 and a dielectric electrically isolating the second bonding contacts 1021. The second bonding contacts 1021 in the second bonding layer 1020 and the surrounding dielectric may be used for hybrid bonding. Here, the second bonding contacts 1021 is in contact with the first bonding contacts 1019 at the bonding interface 106.

In some examples, the peripheral circuit 1012 may further comprise a word line driver/row decoder coupled to a word line (WL) in the second interconnection layer 1022 through the second bonding contacts 1021 in the second bonding layer 1020 and the first bonding contacts 1019 in the first bonding layer 1018 and the first interconnection layer 1016. In other examples, the peripheral circuit 1012 may further comprise a bit line driver/column decoder coupled to a bit line 1023 (BL) in the second interconnection layer 1022 through a second bonding contact 1021 in the second bonding layer 1020 and a first bonding contact 1019 in the first bonding layer 1018 and a first interconnection layer 1016. Here, the second interconnection layer 1022 comprises a bit line 1023 over the second bonding layer 1020 for transmitting an electrical signal.

In some other examples, the stacked first semiconductor structure 102 and the second semiconductor structure 104 may not be connected by bonding, but are integrated on the same substrate (only the first substrate and not the second substrate), and are directly connected through one or more interconnection layers between the first semiconductor structure 102 and the second semiconductor structure 104. Then, the first bonding layer 1018 and the first bonding contact 1019 are not present in the first semiconductor structure 102; the second bonding layer 1020 and the second bonding contact 1021 are not present in the second semiconductor structure 104; and the bonding interface 106 between the first semiconductor structure 102 and the second semiconductor structure 104 is not present.

Referring to FIG. 5, the second semiconductor structure 104 further comprises a memory cell array 1024 on the second interconnection layer 1022, and the memory cell array 1024 may comprise a plurality of memory cells, a second substrate 1048 on the memory cell array 1024, and a third interconnection layer 1050 on the second substrate 1048. The cross section of the dynamic random access memory 100 in FIG. 5 may be taken along the bit line direction (X-axis direction), and one of the bit lines 1023 in the second interconnection layer 1022 extending laterally in the X-axis direction may be coupled to a column of memory cells.

Here, each memory cell may comprise a vertical transistor 1026 and a capacitive structure 1028 coupled to the vertical transistor 1026; the vertical transistor 1026 comprises a semiconductor body 1030 extending vertically (in the Z-axis direction), and a gate structure 1036 in contact with one side of the semiconductor body 1030 in the bit line direction (X-axis direction); in some other examples, the gate structure may also fully surround the semiconductor body, semi-surround the semiconductor body, be located on two opposite sides of the semiconductor body, and the like, and details are not described here again. Here, the gate structure 1036 comprises a gate electrode 1034 and a gate dielectric 1032 located between the gate electrode 1034 and the semiconductor body 1030 in the bit line direction (X-axis direction). In some examples, the gate dielectric 1032 adjoins one side of the semiconductor body 1030, and the gate electrode 1034 adjoins the gate dielectric 1032.

In some examples, the semiconductor body 1030 has two ends (upper end and lower end) in the vertical direction (Z-axis direction), and one end (such as the lower end in FIG. 5) extends beyond the gate dielectric 1032 into an interlayer dielectric (ILD) layer in the vertical direction (Z-axis direction), and the other end of the semiconductor body 1030 (such as the upper end in FIG. 5) is flush with the corresponding end of the gate dielectric 1032. In some other examples, the two ends (upper end and lower end) of the semiconductor body 1030 extend beyond the gate electrode 1034 into the ILD layer in the vertical direction (Z-axis direction) respectively. In other words, the semiconductor body 1030 may have a larger vertical size (e.g., depth in the Z-axis direction) than the vertical size of the gate electrode 1034, and neither the upper end nor the lower end of the semiconductor body 1030 is flush with the corresponding end of the gate electrode 1034. In this way, a short circuit between the bit line 1023 and the gate electrode 1034 or between the gate electrode 1034 and the capacitive structure 1028 may be avoided.

The vertical transistor 1026 may further comprise a source 1038 and a drain 1040 respectively disposed at two ends (upper end and lower end) of the semiconductor body 1030 in the vertical direction (Z-axis direction) (the positions of the source and the drain may be interchanged, and here and the following take the upper end being the source 1038 and the lower end being the drain 1040 as an example). In some implementations, the source 1038 is coupled to the capacitive structure 1028, and the drain 1040 is coupled to the bit line 1023.

Since the gate electrode 1034 may be part of a word line or extend in a word line direction as a word line, the second semiconductor structure 104 of the dynamic random access memory 100 may also comprise a plurality of word lines each extending in a word line direction (Y-axis direction). Here, each word line may be coupled to a row of memory cells.

The vertical transistor 1026 extends vertically through the word line and is in contact with the word line, and the drain 1040 at its lower end is in contact with the bit line 1023. Thus, due to the vertical arrangement of the vertical transistors 1026, the word line and the bit line 1023 may be disposed in different planes in the vertical direction, which simplifies the routing of the word line and the bit line 1023. Here, the vertical transistor 1026 may be arranged in a mirror symmetric manner to increase the density of memory cells in the bit line direction (X-axis direction). Two adjacent vertical transistors 1026 in the bit line direction are mirror symmetric to each other with respect to the trench isolation 1060, that is, the second semiconductor structure 104 may comprise a plurality of trench isolations 1060, each trench isolation 1060 extending in a word line direction (Y-axis direction) parallel to the word line and disposed between semiconductor bodies 1030 of two adjacent rows of the vertical transistor 1026. In some implementations, rows of vertical transistors 1026 separated by trench isolation 1060 are mirror symmetric to each other with respect to trench isolation 1060. It should be understood that trench isolation 1060 may comprise air gaps, and each air gap is disposed laterally between adjacent semiconductor bodies 1030. The second semiconductor structure 104 further comprises a plurality of gate isolations 1062, each gate isolation 1062 extending in a word line direction (Y-axis direction) parallel to the word line and disposed between word lines of two adjacent rows of the vertical transistor 1026. It should be understood that the size of the gate isolation 1062 and the word line in the bit line direction (the X-axis direction) and the size of the trench isolation 1060 in the bit line direction (X-axis direction) may be the same or different; when the sizes of the two in the bit line direction (X-axis direction) are different, the spacing between the plurality of semiconductor bodies 1030 arranged in the bit line direction (X-axis direction) is different, that is, the plurality of semiconductor bodies 1030 arranged along the bit line direction (X-axis direction) are not uniformly arranged.

As shown in FIG. 5, the capacitive structure 1028 may be a vertical capacitor. In some implementations, a conductive structure 1064 is formed between the vertical transistor 1026 (further e.g., the source 1038) and the capacitive structure 1028 to reduce the contact resistance.

As shown in FIG. 5, the second semiconductor structure 104 may also comprise a capacitive contact 1047 in contact with a common plate of the capacitive structure 1028 for coupling the capacitive structure 1028 to the peripheral circuit 1012 or directly coupling the capacitive structure 1028 to ground. In some implementations, the ILD layer forming the capacitive structure 1028 has the same dielectric material, such as silicon oxide, as the two ILD layers into which the semiconductor body 1030 extends. The configuration of the capacitive structure 1028 may comprise any suitable structure and configuration, such as planar capacitors, stacked capacitors, multi-fin capacitors, cylindrical capacitors, trench capacitors, or substrate-plate capacitors.

As shown in FIG. 5, the vertical transistor 1026 extends vertically through the word line and is in contact with the word line, the drain 1040 at its lower end is in contact with the bit line 1023, and the source 1038 at its upper end is in contact with the capacitive structure 1028. That is, due to the vertical arrangement of the vertical transistors 1026, the bit line 1023 and the capacitive structure 1028 may be disposed in different planes in the vertical direction and coupled to opposite ends of the vertical transistor 1026 of the memory cell in the vertical direction. In some implementations, the bit line 1023 and the capacitive structure 1028 are disposed on opposite sides of the vertical transistor 1026 in the vertical direction, which simplifies the routing of the bit line 1023 and reduces the coupling capacitance between the bit line 1023 and the capacitive structure 1028 as compared to memory cells in which the bit line and the capacitive structure are disposed on the same side of the planar transistor.

In some examples, the vertical transistor 1026 is vertically disposed between the capacitive structure 1028 and the bonding interface 106. That is, the vertical transistor 1026 may be arranged closer to the peripheral circuit 1012 of the first semiconductor structure 102/bonding interface 106 than the capacitive structure 1028. As the bit line 1023 and the capacitive structure 1028 are coupled to opposite ends of the vertical transistor 1026, the bit line 1023 (as part of the second interconnection layer 1022) is vertically disposed between the vertical transistor 1026 and the bonding interface 106 to reduce interconnect routing distance and complexity.

In some examples, the second semiconductor structure 104 further comprises a second substrate 1048 disposed over the memory cell array 1024, and a pad out third interconnection layer 1050 disposed over the memory cell array 1024. The pad out third interconnection layer 1050 may comprise interconnects, e.g., contact pads 1054, in one or more ILD layers.

In some examples, the second semiconductor structure 104 further comprises one or more contacts 1052 extending through the pad out third interconnection layer 1050 and the second substrate 1048 to be coupled to the memory cell and the second interconnection layer 1022 through the pad out third interconnection layer 1050. As such, the peripheral circuit 1012 may be coupled to the memory cell through the first interconnection layer 1016 and the second interconnection layer 1022 and the second bonding layer 1020 and the first bonding layer 1018, and the peripheral circuit 1012 and the memory cell array 1024 may be coupled to the external circuit through the contact 1052 and the pad out third interconnection layer 1050.

However, with the development of semiconductor technology, the memory density of the memory is gradually increased, the number of the first bonding contacts and the number of the second bonding contacts are gradually increased, and the number of the metal layers used for coupling the peripheral circuits to the pads is also gradually increased, so that the wiring between the bonding contacts and the metal layer is more complex, in other words, the wiring channel resources between the bonding contacts and the metal layers are affected, and in this case, the area saved in the memory cell array by stacking cannot be effectively utilized.

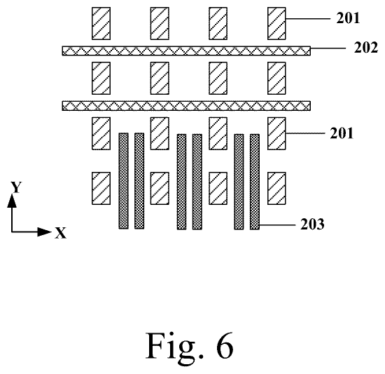

For example, referring to FIG. 6, FIG. 6 is a schematic top view of bonding contacts and a metal layer; where the bonding contacts 201 shown in FIG. 6 may be a schematic top view of the first bonding contacts and the second bonding contacts in the XY plane in the above examples; as shown in FIG. 6, both the metal layer 202 extending in the X-axis direction and the metal layer 203 extending in the Y-axis direction need to bypass the bonding contact 201, so that the wiring resource of the metal layer is limited and the wiring is more complex.

It should be noted that both the metal layer 202 extending along the X-axis direction and the metal layer 203 extending along the Y-axis direction may be connected to the same circuit or connected to different circuits. When the two are connected to the same circuit, that is, when the electrical signals transmitted by the two are the same, at least one end of each of the two is connected, and the heights of the two in the Z-axis direction are the same. When the two are connected to different circuits, that is, the electrical signals transmitted by the two are different, the two need to be electrically isolated; for example, the two may be electrically isolated by different heights in the Z-axis direction. In other words, by disposing a plurality of metal layers at different heights in the Z-axis direction in the memory, and connecting the plurality of metal layers to different circuits, the electrical signal transmission of different circuits is achieved.

However, although the electrical signal transmission of more circuits can be achieved by increasing the number of the metal layers in the Z-axis direction, the efficiency is not high due to the limitation of the bonding contacts (Pepper); instead, the area where the metal layer is located places a more strict requirement on the metal pitch and the square resistance, which increases the process difficulty. In addition, with the improvement of the manufacturing process, the sizes of some devices such as sensing amplification circuit (SA) and word line driver circuit (WL Drv) will be further reduced, and the density of the bonding contacts will rise accordingly, resulting in a larger free area inside the memory block, and a higher requirement on the metal pitch and the square resistance, so that the effect of improving the manufacturing process on reducing the die size of the memory is not significant.

In view of this, based on one or more of the above problems, the present disclosure provides a semiconductor device comprising a first semiconductor structure and a second semiconductor structure; the first semiconductor structure comprises a first bonding layer, a peripheral circuit layer comprising a logic circuit, and an interconnection layer; the second semiconductor structure comprises a memory cell layer comprising DRAM memory cells and a second bonding layer; the second bonding layer is bonded to the first bonding layer; where the first semiconductor structure further comprises: a first interconnection structure between the logic circuit and the first bonding layer; a contact structure penetrating through the semiconductor layer where the logic circuit is located; and a second interconnection structure and a pad in the interconnection layer; the logic circuit is connected to the pad through the first interconnection structure, the contact structure, and the second interconnection structure.

In this way, by disposing the pad on one side of two opposite sides of the peripheral circuit layer away from the memory array layer, and disposing the first interconnection structure and the contact structure in the peripheral circuit layer and disposing the second interconnection structure in the interconnection layer on one side of two opposite sides of the peripheral circuit layer away from the memory array layer, the logic circuit in the peripheral circuit layer is connected to the pad through the first interconnection structure, the contact structure and the second interconnection structure, thereby achieving the connection between the logic circuit and the external device. In other words, in this way, in the process of implementing signal intercommunication between the logic circuit and the external device, the connection structure (for example, the first interconnection structure, the contact structure and the second interconnection structure) used for connecting the logic circuit does not need to penetrate through the memory array layer. Instead, by implementing the signal lead-out towards the direction away from the memory array layer through the connection structure, the influence of wiring between the connection structure and the bonding contacts in the bonding layer is avoided, the wiring resources of the bonding contacts are saved, the process difficulty is reduced, the device reliability is improved, the device size can be further reduced, and the storage density is improved.

The structure of the semiconductor device is described in detail below with reference to the drawings. In each direction that may be used in the following description, the first direction is the Z-axis direction, the second direction intersects with the third direction, and both are perpendicular to the first direction. For example, the second direction is the X-axis direction, and the third direction is the Y-axis direction; the X-axis direction, the Y-axis direction and the Z-axis direction may be perpendicular to each other.

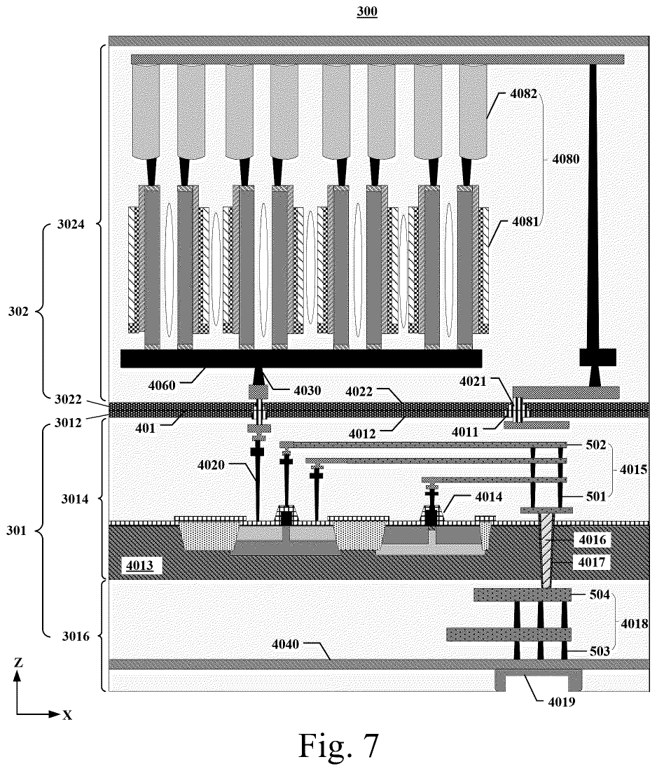

Referring to FIG. 7, FIG. 7 is a schematic structural cross-sectional view of a semiconductor device 300 in an XZ plane. Herein, the semiconductor device 300 comprises a first semiconductor structure 301 and a second semiconductor structure 302 stacked along the Z-axis direction. It should be understood that the example of FIG. 7 shows that the second semiconductor structure 302 is located above the first semiconductor structure 301, and in other examples, the first semiconductor structure 301 may also be located above the second semiconductor structure 302.

Here, the first semiconductor structure 301 comprises a first bonding layer 3012, a peripheral circuit layer 3014, and an interconnection layer 3016 stacked in sequence along the Z-axis direction; the second semiconductor structure 302 comprises a second bonding layer 3022 and a memory array layer 3024 stacked along a Z-axis direction, and the memory array layer 3024 comprises DRAM memory cells 4080. Here, the DRAM memory cell 4080 comprises a transistor 4081 and a capacitive structure 4082; in some other examples, the DRAM memory cell may also be another architecture, such as 2T0C, which is not limited in the present disclosure.

The first semiconductor structure 301 and the second semiconductor structure 302 are bonded through a bonding interface 401. In an example, the first bonding layer 3012 may comprise first bonding contacts 4011 and a first insulating layer 4012 that isolates the first bonding contacts 4011; the second bonding layer 3022 may comprise second bonding contacts 4021 and a second insulating layer 4022 that isolates the second bonding contacts 4021; the first bonding contacts 4011 and the second bonding contacts 4021 are bonded, and the first insulating layer 4012 and the second insulating layer 4022 are bonded, so that the first bonding layer 3012 and the second bonding layer 3022 are bonded and a bonding interface 401 is formed where the two are bonded. The composition materials of the first bonding contacts 4011 and the second bonding contacts 4021 comprise a conductive material, where the conductive material may be one of a metal material (e.g., aluminum, copper, tungsten, titanium, tantalum, etc.), a doped semiconductor material (e.g., doped silicon, doped germanium, etc.), a conductive metal nitride (e.g., titanium nitride (TiN), tantalum nitride, etc.), and a metal semiconductor compound (e.g., tungsten silicide, cobalt silicide, titanium silicide, etc.).

With continued reference to FIG. 7, the peripheral circuit layer 3014 comprises a semiconductor layer 4013, and the composition materials of the semiconductor layer 4013 comprise, but are not limited to, silicon (Si). At least part of the logic circuit 4014 is formed in the semiconductor layer 4013; for example, the logic circuit 4014 may comprise a decoding circuit, a driving circuit, a sensing amplification circuit, a row hammer refresh circuit, and the like.

The peripheral circuit layer 3014 further comprises a first interconnection structure 4015 and a contact structure 4016. The first interconnection structure 4015 is located between the logic circuit 4014 and the first bonding layer 3012, and the contact structure 4016 penetrates through the semiconductor layer 4013 along the Z-axis direction. One end of the first interconnection structure 4015 is connected to the logic circuit 4014, and the other end is connected to the contact structure 4016. In this way, the electrical signal of the logic circuit 4014 may be led out from the front side (the side close to the second semiconductor structure) of the logic circuit 4014, and transmitted to the back side (the side away from the second semiconductor structure) of the logic circuit 4014. Here, the composition materials of the first interconnection structure 4015 and the contact structure 4016 are conductive materials.

In some examples, referring to FIG. 7, the first interconnection structure 4015 comprises a plurality of first connection structures 501 extending along the Z-axis direction and at least one first metal layer 502 extending along a direction (such as at least one of the X-axis direction or the Y-axis direction) perpendicular to the Z-axis direction; the first connection structure 501 is connected to the first metal layer 502, and the plurality of first metal layers 502 and the plurality of first connection structures 501 are alternately arranged along the Z-axis direction. A plurality of first connection structures 501 may also be disposed between two adjacent first metal layers 502. The shape of the first connecting structure 501 and the shape of the first metal layer 502 may be set selectively according to actual requirements. The first connection structure 501 and the first metal layer 502 are both used for electrical signal transmission, and the composition materials of them are both conductive materials.

In some examples, the logic circuit may comprise a plurality of different circuits, such as a decoding circuit, a driving circuit, a sensing amplification circuit, and a row hammer refresh circuit, the first interconnection structure 4015 comprises a plurality of first metal layers 502, and the decoding circuit, the driving circuit, the sensing amplification circuit, and the row hammer refresh circuit may be respectively connected to different first metal layers 502 to transmit different circuit signals to the pad(s) through the different first metal layers.

In some examples, the contact structure 4016 may also extend to two ends along the Z-axis direction respectively. Here, the first end of the contact structure 4016 is connected to the first metal layer 502 in the first interconnection structure; and the second end of the contact structure 4016 is connected to the second interconnection structure 4018. However, it should be understood that, in some other examples, the first end of the contact structure 4016 may also be connected to the first connection structure 501 in the first interconnection structure.

In some examples, there may be a plurality of contact structures 4016 arranged at intervals in a direction (for example, at least one of the X-axis direction or the Y-axis direction) perpendicular to the Z-axis direction. For example, the plurality of contact structures 4016 may be arranged at intervals along the X-axis direction, or may be arranged at intervals along the Y-axis direction, or may be arranged in an array along the X-axis direction and the Y-axis direction. It should be noted that a plurality of first metal layers 502 may be connected to the same contact structure 4016 through the first connection structure 501, or may be connected to different contact structures 4016.

In some examples, the first semiconductor structure further comprises: a dielectric layer 4017 penetrating through the semiconductor layer 4013 along the Z-axis direction and surrounding the sidewall of the contact structure 4016 for isolating the contact structure 4016 and the semiconductor layer 4013 to prevent electrical short circuits. The composition material of the dielectric layer 4017 is an insulating material, such as silicon oxide (SiO₂), silicon nitride (Si₃N₄), and the like.

With continued reference to FIG. 7, an interconnection layer 3016 is disposed on one side of two opposite sides of the peripheral circuit layer 3014 along the Z-axis direction away from the first bonding layer 3012, and a second interconnection structure 4018 and a pad 4019 are disposed in the interconnection layer 3016.

Here, the second interconnection structure 4018 comprises a plurality of second connection structures 503 extending along the Z-axis direction and at least one second metal layer 504 extending in a direction perpendicular to the Z-axis direction; the second connection structure 503 is connected to the second metal layer 504, and the plurality of second metal layers 504 and the plurality of second connection structures 503 are alternately arranged along the Z-axis direction. A plurality of second connection structures 503 may also be disposed between two adjacent second metal layers 504. The shape of the second connecting structure 503 and the shape of the second metal layer 504 may be set selectively according to actual requirements. Both the second connection structure 503 and the second metal layer 504 are used for electrical signal transmission, and the composition materials of them are conductive materials.

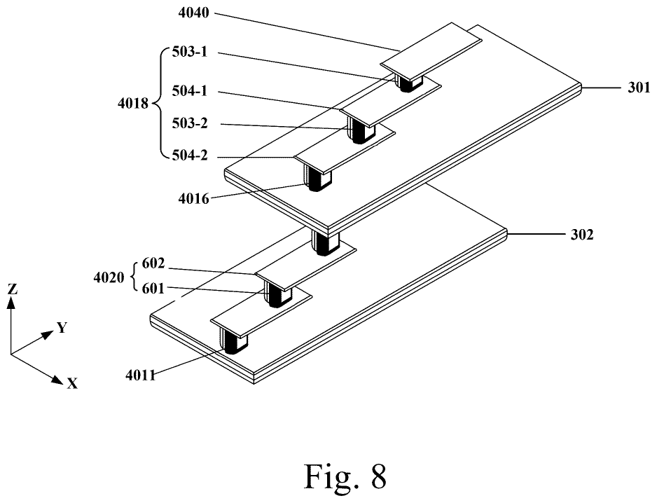

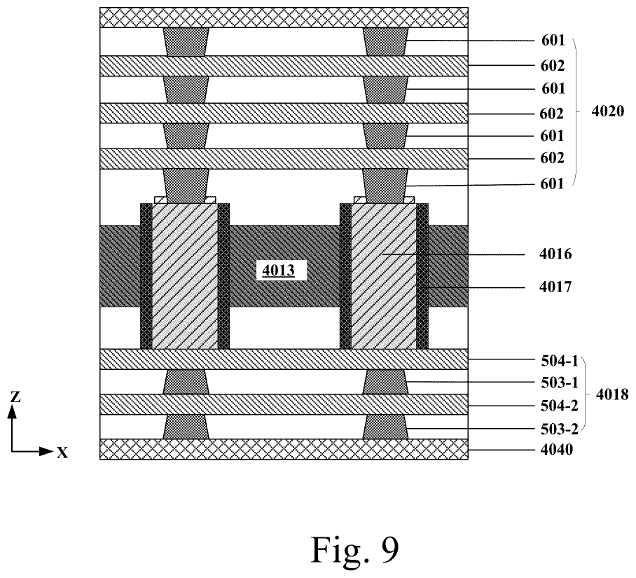

In some examples, when there are a plurality of second metal layers, the arrangement of the plurality of second metal layers and the plurality of second connection structures may be set selectively according to actual requirements. For example, referring to FIG. 8 and FIG. 9, FIG. 8 is a schematic perspective view of a semiconductor device; and FIG. 9 is a schematic cross-sectional view of the semiconductor device shown in FIG. 8 in an XZ plane. Herein, the second connection structure comprises a first sub-connection structure 503-1 and a second sub-connection structure 503-2, the second metal layer 504 comprises a first second metal layer 504-1 and a second second metal layer 504-2, and the first sub-connection structure 503-1, the first second metal layer 504-1, the second sub-connection structure 503-2, and the second second metal layer 504-2 are sequentially arranged along the Z-axis direction.

Likewise, in order to transmit electrical signals of different circuits, different second metal layers may be correspondingly connected to different circuits through different contact structures, and different second connection structures may also be correspondingly connected to different circuits through different contact structures, in this way, parallelism of electrical signal transmission may be improved, and in turn the operation performance of the semiconductor device is improved.

Referring to FIG. 7, FIG. 8, and FIG. 9, the second end of the contact structure 4016 is connected to the second metal layer 504 (such as the first second metal layer 504-2); in some other examples, the second end of the contact structure 4016 may also be connected to the second connection structure 503 (such as the second sub-connection structure 503-2). The first and second ends of the contact structure 4016 are two opposite ends of the contact structure 4016 in the Z-axis direction.

Referring back to FIG. 7, the pad 4019 in the interconnection layer 3016 is connected to the second interconnection structure 4018, and here, the pad 4019 is connected to the second connection structure 503 in the second interconnection structure, and the pad 4019 may be configured to implement electrical signal intercommunication between the logic circuit and the external device. In an example of the present disclosure, there may be one or more pads 4019. The shape of the pad 4019 may be set selectively according to actual requirements. The composition material of the pad 4019 comprises, but are not limited to, copper (Cu), aluminum (Al), tungsten (W), cobalt (Co), or other conductive composite materials.

In some examples, the plurality of second connection structures 503 may be connected to the same pad 4019, or may be respectively connected to different pads 4019. In this way, the electrical signal of the logic circuit 4014 can be transmitted to the pad 4019 through the first metal layer 502, the first connection structure 501, the contact structure 4016, the second metal layer 504, and the second connection structure 507, and in turn the electrical signal intercommunication between the logic circuit 4014 and the external device is achieved.

In some examples, referring to FIG. 7, FIG. 8, and FIG. 9, the interconnection layer 3016 further comprises a redistribution layer (RDL) 4040 located between the second interconnection structure 4018 and the pad 4019 and configured to redistribute the I/O electrical signal connections, thereby achieving a higher density of signal connections, so as to meet the requirements of high-performance computing and mobile device for package miniaturization. The composition material of the redistribution layer 4040 may comprise copper or aluminum or other suitable conductive materials. It should be noted that the examples of FIG. 8 and FIG. 9 show only a local structure of the metal layer, the connection structure and the redistribution layer, and some structures such as pads, circuits and the like in FIG. 7 are not shown.

In some examples, referring to FIG. 7, a third interconnection structure 4020 is further disposed in the peripheral circuit layer 3014, one end of the third interconnection structure 4020 is connected to the first bonding contact 4011, and the other end is connected to some circuits in the peripheral circuit. A fourth interconnection structure 4030 is disposed in the memory array layer 3024, one end of the fourth interconnection structure 4030 is connected to the second bonding contact 4021, and the other end is connected to the DRAM memory cell 4080 through the bit line 4060. In this way, electrical connection between some circuits in the peripheral circuit and the DRAM memory cell 4080 can be achieved.

For example, with reference to FIG. 8 and FIG. 9, the third interconnection structure 4020 comprises a third connection structure 601 and a third metal layer 602 connected to each other, the number of the third connection structures 601 may comprise one (refer to FIG. 8) or more (referring to FIG. 9), and the number of layers of the third metal layer 602 may comprise one layer (refer to FIG. 8) or multiple layers (refer to FIG. 9). Herein, the plurality of third connection structures 601 and the plurality of third metal layers 602 are alternately arranged at intervals along the Z-axis direction. The third connecting structure 601 and the third metal layer 602 each comprises a conductive material.

It should be noted that the logic circuit connected to the third interconnection structure may be different from the logic circuit connected to the first interconnection structure, for example, the third interconnection structure is connected to the circuit in the logic circuit for implementing signal interaction inside the semiconductor device, and the first interconnection structure is connected to the circuit in the logic circuit for implementing signal interaction with the external device, thereby improving the operation performance and reliability of the semiconductor device.

In the examples of the present disclosure, on one hand, only the associated wiring (e.g., the third interconnection structure) connected to the second bonding contact of the second semiconductor structure and the short connection line inside the device are retained on the front side of the first semiconductor structure (e.g., the side bonded to the second semiconductor structure), so that the wiring difficulty between the first semiconductor structure and the second semiconductor structure can be reduced; meanwhile, the bit line couple (BL Couple) generated between the first semiconductor structure and the bit line 4060 can also be reduced, thereby improving the reliability of the semiconductor device; on the other hand, the first interconnection structure, the second interconnection structure, the contact structure and the pad are disposed on the back side of the first semiconductor structure for the long connection line inside the device, such as a global signal and a power mesh. In this way, since the wiring resource on the back side of the first semiconductor structure is not limited, the requirement on the metal pitch and the connection structure pitch can be reduced, thereby reducing the process difficulty and reducing the manufacturing cost; and on the other hand, the wiring resource inside the device is increased, so that the free area inside the device is easier to be fully utilized, and as the process iterates toward smaller direction, the effect of reducing the die size of the semiconductor device is more significant.

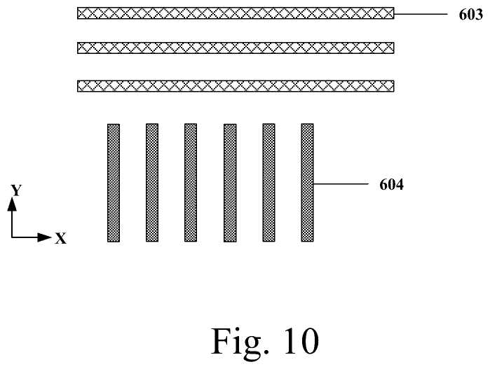

For example, referring to FIG. 10, FIG. 10 is a schematic top view of a first metal layer on the back side of the first semiconductor structure in the XY plane, where the degree of freedom for selecting the pitch of the metal layer 603 extending along the X-axis direction and the pitch of the metal layer 604 extending along the Y-axis direction is higher.

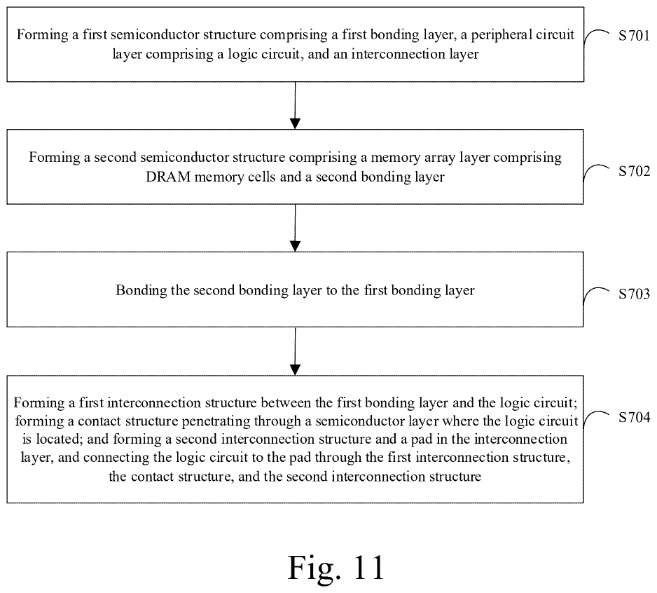

Based on the foregoing semiconductor device, an example of the present disclosure further provides a manufacturing method of a semiconductor device. Herein, the semiconductor device comprises a semiconductor structure. Referring to FIG. 11, FIG. 11 is a schematic flowchart of a manufacturing method of a semiconductor structure according to an example of the present disclosure; the method comprises:

Operation S701: forming a first semiconductor structure comprising a first bonding layer, a peripheral circuit layer comprising a logic circuit, and an interconnection layer.

Operation S702: forming a second semiconductor structure comprising a memory array layer comprising DRAM memory cells and a second bonding layer.

Operation S703: bonding the first bonding layer to the second bonding layer.

Operation S704: forming a first interconnection structure between the first bonding layer and the logic circuit; forming a contact structure penetrating through a semiconductor layer where the logic circuit is located; and forming a second interconnection structure and a pad in the interconnection layer, and connecting the logic circuit to the pad through the first interconnection structure, the contact structure, and the second interconnection structure.

It should be understood that the operations shown in FIG. 11 are not exclusive or that other operations may be performed before, after, or between any of the illustrated operations. The operations shown in FIG. 11 may be sequentially adjusted according to actual requirements; for example, operation S704 may be completed before operation S703. The formation process of the semiconductor structure will be described in detail below with reference to the drawings.

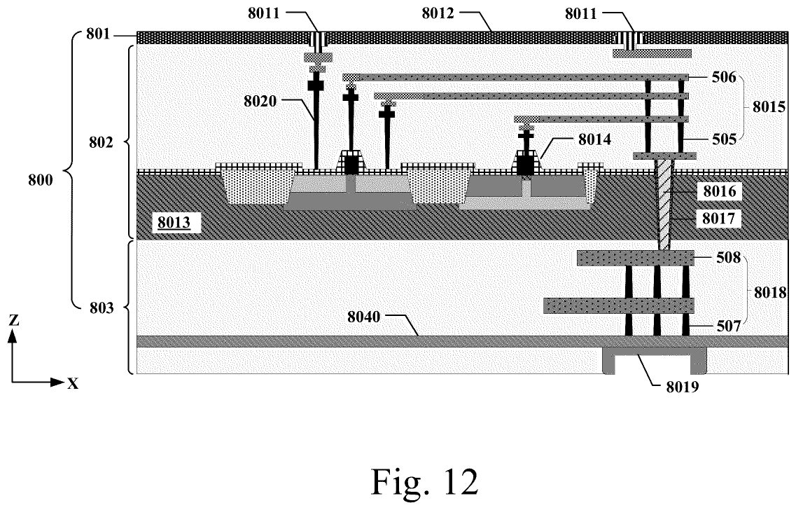

In some examples, operation S701 and operation S704 are performed, and referring to FIG. 12, the first semiconductor structure 800 is formed. The method comprises: forming a first bonding layer 801, a peripheral circuit layer 802 and an interconnection layer 803 sequentially stacked along the Z-axis direction, and forming first bonding contacts 8011 and a first insulating layer 8012 isolating the first bonding contacts 8011 in the first bonding layer 801. The composition material of the first bonding contacts 8011 comprises a conductive material. The manufacturing method of the first bonding contacts 8011 comprises, but is not limited to, an etching process and a deposition process. The deposition process comprises for example, but is not limited to, chemical vapor deposition (CVD), low pressure chemical vapor deposition (LPCVD), plasma enhanced chemical vapor deposition (PECVD), physical vapor deposition (PVD), atomic layer deposition (ALD), or the like.

The method further comprises: forming a semiconductor layer 8013 in the peripheral circuit layer 802, and forming at least a portion of the logic circuit 8014 in the semiconductor layer 8013. The composition material of the semiconductor layer 8013 comprises silicon. The logic circuit 8014 comprises a transistor. The method for forming the transistor is well known and will not be repeated here. A first interconnection structure 8015 is formed in the peripheral circuit layer 802 and between the logic circuit 8014 and the first bonding layer 801.

In some examples, forming the first interconnection structure 8015 between the first bonding layer 801 and the logic circuit 8014 comprises: forming a first connection structure 505 extending along the Z-axis direction and at least one first metal layer 506 extending along at least one of the X-axis direction or the Y-axis direction between the first bonding layer and the logic circuit, and connecting the first connection structure 505 to the first metal layer 506. When there are a plurality of first metal layer 506, the plurality of first metal layers 506 and the plurality of first connection structures 505 are alternately arranged along the Z-axis direction. It should be noted that the number of the first connection structures 505 located between the two first metal layers 506 may comprise one or more. The first connection structure 505 and the first metal layer 506 are both used for electrical signal transmission, and the materials of them are conductive materials. For example, the first connection structure 505 may be formed by using a through silicon via (TSV) technology, where the TSV technology comprises an etching process, a deposition process, an electroplating process, a chemical mechanical polishing (CMP) process, or the like. Here, the etching process comprises, for example, deep reactive ion etching (DRIE). The first metal layer 506 may be formed by, for example, a deposition process.

In some examples, the method further comprises: forming a decoding circuit, a driving circuit, an amplification circuit and a row hammer refresh circuit in the peripheral circuit layer 802 to form a logic circuit 8014; and forming a plurality of first metal layers 506, and connecting the decoding circuit, the driving circuit, the sensing amplification circuit and the row hammer refresh circuit to different first metal layers respectively, so as to achieve electrical signal transmission of different circuits and improve the parallelism of electrical signal transmission, thereby improving the operation performance of the semiconductor device.

In some examples, the method further comprises: forming a plurality of contact structures 8016 penetrating through the semiconductor layer where the logic circuit is located, the contact structure 8016 extending along the Z-axis direction, and the number of the contact structures 8016 may comprise one or more; where the plurality of contact structures 8016 are arranged at intervals in at least one of the X-axis direction or the Y-axis direction. The composition material of the contact structure 8016 comprises a conductive material. The method of forming the contact structure 8016 comprises, but is not limited to, an etching process, a deposition process, or the like.

In some examples, a method of forming the contact structure 8016 may comprise: forming a via penetrating through the semiconductor layer 8013 where the logic circuit is located along the Z-axis direction; forming a dielectric layer 8017 on a sidewall of the via; forming the contact structure 8016 in the via where the dielectric layer 8017 is formed. In this way, the dielectric layer 8017 may surround the sidewall of the contact structure 8016 for isolating the contact structure 8016 and the semiconductor layer 8013, thereby preventing electrical short circuit. The composition material of the dielectric layer 8017 is an insulating material such as silicon oxide (SiO₂), silicon nitride (Si₃N₄), and the like. The method of forming the dielectric layer 8017 comprises, but is not limited to, a deposition process.

In some examples, the method further comprises: forming a second interconnection structure 8018 in the interconnection layer 803. Herein, a method of forming the second interconnection structure 8018 comprises: forming a plurality of second connection structures 507 extending along the Z-axis direction, and at least one second metal layer 508 extending along at least one of the X-axis direction or the Y-axis direction, and connecting the second connection structure 507 to the second metal layer 508. Here, there may be a plurality of second metal layers 508, and the plurality of second metal layers 508 and the plurality of second connection structures 507 are alternately arranged along the Z-axis direction; and the number of the second connection structures 507 between the two second metal layers 508 may comprise one or more, and in this way, the parallelism of signal transmission may be improved. The method of forming the second connection structure is the same as that of the first connection structure, and the method of forming the second metal layer is the same as that of the first metal layer.

In some examples, the method further comprises: forming a third interconnection structure 8020 in the peripheral circuit layer 802, one end of the third interconnection structure 8020 is connected to the logic circuit, and the other end is connected to the first bonding contact for implementing electrical connection between the logic circuit and the second semiconductor structure. It should be noted that the logic circuit connected to the third interconnection structure 8020 may be different from the logic circuit connected to the first interconnection structure 8015. For example, the third interconnection structure 8020 is connected to the circuit in the logic circuit for implementing signal interaction inside the semiconductor device, and the first interconnection structure 8015 is connected to the circuit in the logic circuit for implementing a signal interaction with the external device. In this way, the reliability and the operation performance of the semiconductor device can be improved.

In some examples, the method further comprises: forming a pad 8019 in the interconnection layer 803. In this way, the logic circuit 8014 may be connected to the pad 8019 through the first interconnection structure 8015, the contact structure 8016, and the second interconnection structure 8018, to implement electrical signal connection between the logic circuit and the external device.

In some examples, the method further comprises: forming a redistribution layer 8040 between the second interconnection structure 8018 and the pad 8019 in the interconnection layer 803. The redistribution layer 8040 is configured to redistribute the I/O electrical signal connections, thereby achieving a higher density of signal connections to meet the requirements of high-performance computing and mobile devices for package miniaturization. The composition material of the redistribution layer 8040 may comprise copper or aluminum or other suitable conductive materials. The method of forming the redistribution layer 8040 is well known in the related art and will not be repeated here.

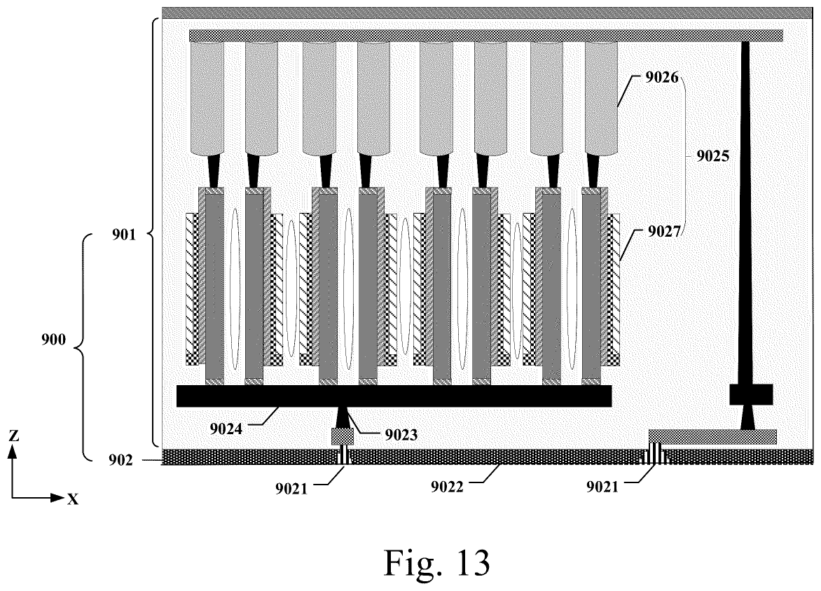

In some examples, operation S702 is performed, and referring to FIG. 13, a second semiconductor structure 900 is formed. The method comprises: forming a memory array layer 901 and a second bonding layer 902 stacked along a Z-axis direction.

The method comprises: forming second bonding contacts 9021 and a second insulating layer 9022 isolating the second bonding contacts 9021 in the second bonding layer 902. There may be a plurality of second bonding contacts 9021. The composition material of the second bonding contacts 9021 comprises a conductive material. The manufacturing method of the second bonding contacts 9021 comprises, but is not limited to, an etching process and a deposition process.

In some examples, the method further comprises: forming a DRAM memory cell 9025 in the memory array layer 901, the DRAM memory cell 9025 comprising a transistor 9027 and a capacitive structure 9026; in some other examples, the DRAM memory cell 9025 may be another structure, such as 2T0C and the like. The method of forming the DRAM memory cell 9025 is well known and will not be repeated here.

In some examples, the method further comprises: forming a bit line 9024 coupled to the DRAM memory cell 9025 in the memory array layer 901, and forming a fourth interconnection structure 9023 connected to the bit line 9024. The other end of the fourth interconnection structure 9023 is connected to the second bonding contact 9021.

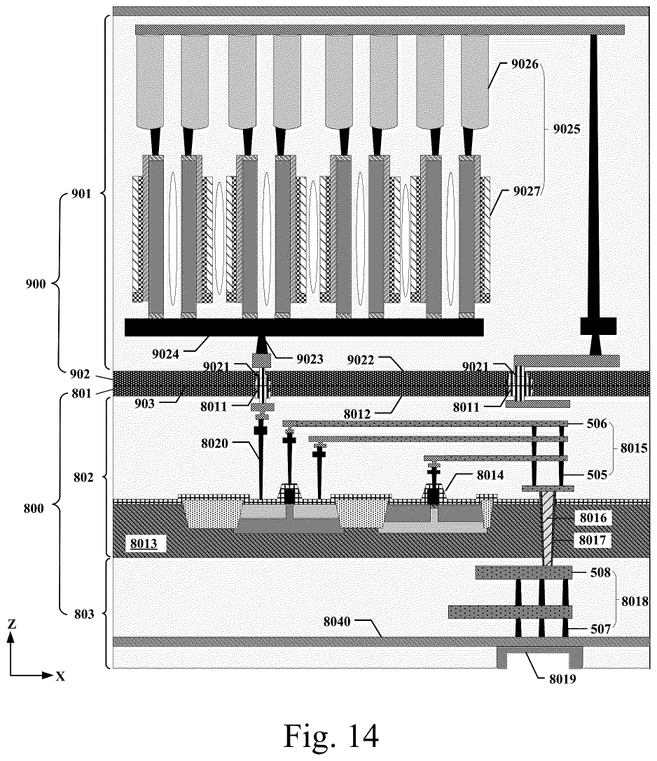

In some examples, operation S703 is performed, referring to FIG. 14, the first semiconductor structure 800 is bonded to the second semiconductor structure 900. The method comprises: bonding the first bonding contacts 8011 and the second bonding contacts 9021, and bonding the first insulating layer 8012 and the second insulating layer 9022 to bond the first bonding layer 801 and the second bonding layer 902; wherein a bonding interface 903 is formed where the first bonding layer 801 and the second bonding layer 902 are bonded.

In this way, some circuits in the logic circuit may be connected with the DRAM memory cell through the third interconnection structure, and some circuits may be connected with the external device through the first interconnection structure, the contact structure and the second interconnection structure. In one aspect, the first interconnection structure, the contact structure and the second interconnection structure do not need to penetrate through the memory array layer, so that the influence of the wiring between them and the bonding contacts in the bonding layer is avoided, the wiring resource of the bonding contacts is saved, the process difficulty is reduced, and the reliability of the device is improved. In another aspect, the bit line couple (BL couple) generated between the first semiconductor structure and the bit line can be reduced, and the reliability of the semiconductor device is improved. In still another aspect, different transmission paths are selected according to different circuits, the signal transmission parallelism is improved, meanwhile, the requirement on the metal pitch and the connection structure pitch is reduced, the process difficulty is reduced, the manufacturing cost is reduced, and the reliability of the device is improved. In yet another aspect, the wiring resource inside the semiconductor device is increased, so that the free area inside the device is fully utilized, and thereby the memory density is improved.

According to an aspect of the present disclosure, a memory system is provided, comprising: the semiconductor device according to the above examples of the present disclosure; and a memory controller connected to the semiconductor device and configured to control the semiconductor device.

According to an aspect of the present disclosure, a semiconductor device is provided, comprising: a first semiconductor structure comprising a first bonding layer, a peripheral circuit layer comprising a logic circuit, and an interconnection layer; a second semiconductor structure comprising a memory array layer comprising DRAM memory cells and a second bonding layer; the second bonding layer being bonded to the first bonding layer; wherein the first semiconductor structure further comprises: a first interconnection structure between the logic circuit and the first bonding layer; a contact structure penetrating through a semiconductor layer where the logic circuit is located; and a second interconnection structure and a pad in the interconnection layer; the logic circuit being connected to the pad through the first interconnection structure, the contact structure, and the second interconnection structure.

In some examples, the first interconnection structure comprises a plurality of first connection structures extending along a first direction and at least one first metal layer extending along at least one of a second direction or a third direction; the at least one first metal layer and the plurality of first connection structures are alternately arranged along the first direction; the first direction is a stacking direction of the first semiconductor structure and the second semiconductor structure; and the second direction intersects with the third direction, and the second direction and the third direction are both perpendicular to the first direction.

In some examples, the logic circuit comprises a decoding circuit, a driving circuit, a sensing amplification circuit, and a row hammer refresh circuit; the first interconnection structure comprises a plurality of the first metal layers; wherein the decoding circuit, the driving circuit, the sensing amplification circuit, and the row hammer refresh circuit are respectively connected to different one of the first metal layers.

In some examples, the second interconnection structure comprises a plurality of second connection structures extending along the first direction and at least one second metal layer extending along at least one of the second direction or the third direction; and the at least one second metal layer and a plurality of the second connection structures are alternately arranged along the first direction.

In some examples, there are a plurality of the contact structures; a plurality of the contact structures are arranged at intervals in at least one of the second direction or the third direction.

In some examples, the composition materials of the pad, the first connection structure, the second connection structure, the first metal layer, the second metal layer and the contact structure each comprise a conductive material.

In some examples, a plurality of the second connection structures arranged along at least one of the second direction or the third direction are connected to the same pad.

In some examples, the first semiconductor structure further comprises: a dielectric layer penetrating through the semiconductor layer along the first direction and surrounding a sidewall of the contact structure.

In some examples, the first bonding layer comprises first bonding contacts and a first insulating layer isolating the first bonding contacts; the second bonding layer comprises second bonding contacts and a second insulating layer isolating the second bonding contacts; and the first bonding contacts and the second bonding contacts are bonded, and the first insulating layer and the second insulating layer are bonded.

According to an aspect of the present disclosure, a memory system is provided, comprising: the semiconductor device according to the above examples of the present disclosure; and a memory controller connected to the semiconductor device and configured to control the semiconductor device.

According to an aspect of the present disclosure, a manufacturing method of a semiconductor device is provided, comprising: forming a first semiconductor structure comprising a first bonding layer, a peripheral circuit layer comprising a logic circuit, and an interconnection layer; forming a second semiconductor structure comprising a memory array layer comprising DRAM memory cells and a second bonding layer; bonding the first bonding layer to the second bonding layer; wherein the method further comprises: forming a first interconnection structure between the first bonding layer and the logic circuit; forming a contact structure penetrating through a semiconductor layer where the logic circuit is located; and forming a second interconnection structure and a pad in the interconnection layer, and connecting the logic circuit to the pad through the first interconnection structure, the contact structure, and the second interconnection structure.

In some examples, the forming the first interconnection structure between the first bonding layer and the logic circuit comprises: forming a first connection structure extending along a first direction and at least one first metal layer extending along at least one of a second direction or a third direction between the first bonding layer and the logic circuit, and alternately arranging the at least one first metal layer and a plurality of the first connection structures along the first direction; wherein the first direction is a stacking direction of the first semiconductor structure and the second semiconductor structure, the second direction intersects with the third direction, and the second direction and the third direction are both perpendicular to the first direction.

In some examples, the method further comprises: forming a decoding circuit, a driving circuit, an amplification circuit and a row hammer refresh circuit in the peripheral circuit layer to form the logic circuit; and forming a plurality of the first metal layers, and connecting the decoding circuit, the driving circuit, the sensing amplification circuit and the row hammer refresh circuit to different one of the first metal layers respectively.

In some examples, the forming the second interconnection structure in the interconnection layer comprises: forming a plurality of second connection structures extending along the first direction and at least one second metal layer extending along at least one of the second direction or the third direction in the interconnection layer, and alternately arranging the at least one second metal layer and a plurality of the second connection structures along the first direction.

In some examples, the forming the contact structure penetrating through the semiconductor layer where the logic circuit is located comprises: forming a plurality of contact structures penetrating through the semiconductor layer where the logic circuit is located, where the plurality of contact structures are arranged at intervals in at least one of the second direction or the third direction.

In some examples, the forming the contact structure penetrating through the semiconductor layer where the logic circuit is located comprises: forming a via penetrating through the semiconductor layer where the logic circuit is located along the first direction; forming a dielectric layer on a sidewall of the via; and forming a contact structure in the via where the dielectric layer is formed.

In some examples, the bonding the second bonding layer to the first bonding layer comprises: forming first bonding contacts and a first insulating layer isolating the first bonding contacts in the first bonding layer; forming second bonding contacts and a second insulating layer isolating the second bonding contacts in the second bonding layer; bonding the first bonding contacts and the second bonding contacts, and bonding the first insulating layer and the second insulating layer to bond the first bonding layer and the second bonding layer.

In the example of the present disclosure, the peripheral circuit layer is bonded with the memory array layer through the bonding layer(s), where by disposing the pad on one side of two opposite sides of the peripheral circuit layer away from the memory array layer, and disposing the first interconnection structure and the contact structure in the peripheral circuit layer and disposing the second interconnection structure in the interconnection layer on one side of two opposite sides of the peripheral circuit layer away from the memory array layer, such that the logic circuit in the peripheral circuit layer is connected to the pad through the first interconnection structure, the contact structure and the second interconnection structure, thereby achieving the connection between the logic circuit and the external device. In other words, in this way, in the process of implementing signal intercommunication between the logic circuit and the external device, the connection structure (for example, the first interconnection structure, the contact structure and the second interconnection structure) used for connecting the logic circuit may not need to penetrate through the memory array layer. Instead, by implementing the signal lead-out towards the direction away from the memory array layer through the connection structure, the influence of wiring between the connection structure and the bonding contacts in the bonding layer is avoided, the wiring resources of the bonding contacts are saved, the process difficulty is reduced, the device reliability is improved, the device size can be further reduced, and the storage density is improved.

The above detailed description is only an example of the present disclosure, but the protection scope of the present disclosure is not limited thereto, and changes or replacements that may be easily conceived by any person skilled in the art within the technical scope of the present disclosure fall within the protection scope of the present disclosure. Therefore, the protection scope of the present disclosure should be subject to the protection scope of the claims.

What is claimed is:

1. A semiconductor device, comprising:
a first semiconductor structure including a first bonding layer, a peripheral circuit layer including a logic circuit, and an interconnection layer; and
a second semiconductor structure including a memory array layer including DRAM memory cells and a second bonding layer; the second bonding layer being bonded to the first bonding layer;
wherein the first semiconductor structure further includes: a first interconnection structure between the logic circuit and the first bonding layer; a contact structure penetrating through a semiconductor layer where the logic circuit is located; and a second interconnection structure and a pad in the interconnection layer; and the logic circuit is connected to the pad through the first interconnection structure, the contact structure, and the second interconnection structure.

2. The semiconductor device of claim 1, wherein the first interconnection structure includes a plurality of first connection structures extending along a first direction and at least one first metal layer extending along at least one of a second direction or a third direction; the at least one first metal layer and the plurality of first connection structures are alternately arranged along the first direction; the first direction is a stacking direction of the first semiconductor structure and the second semiconductor structure; and the second direction intersects with the third direction, and the second direction and the third direction are both perpendicular to the first direction.

3. The semiconductor device of claim 2, wherein the logic circuit includes a decoding circuit, a driving circuit, a sensing amplification circuit, and a row hammer refresh circuit; and the first interconnection structure includes a plurality of the at least one first metal layer; and
wherein the decoding circuit, the driving circuit, the sensing amplification circuit, and the row hammer refresh circuit are respectively connected to a different one of the at least one first metal layer.

4. The semiconductor device of claim 2, wherein the second interconnection structure includes a plurality of second connection structures extending along the first direction and at least one second metal layer extending along at least one of the second direction or the third direction; and the at least one second metal layer and the plurality of second connection structures are alternately arranged along the first direction.

5. The semiconductor device of claim 4, wherein there are a plurality of contact structures; and ones of the plurality of contact structures are arranged at intervals along at least one of the second direction or the third direction.

6. The semiconductor device of claim 5, wherein composition materials of the pad, the plurality of first connection structures, the plurality of second connection structures, the first metal layer, the second metal layer and the plurality of contact structures each include a conductive material.

7. The semiconductor device of claim 5, wherein the ones of the plurality of second connection structures arranged at intervals along at least one of the second direction or the third direction are connected to a same pad.

8. The semiconductor device of claim 7, wherein the first semiconductor structure further includes: a dielectric layer penetrating through the semiconductor layer along the first direction and surrounding a sidewall of the contact structure.

9. The semiconductor device of claim 1, wherein the first bonding layer includes first bonding contacts and a first insulating layer isolating the first bonding contacts; the second bonding layer includes second bonding contacts and a second insulating layer isolating the second bonding contacts; and the first bonding contacts and the second bonding contacts are bonded, and the first insulating layer and the second insulating layer are bonded.

10. A memory system, comprising:
a semiconductor device, including:
a first semiconductor structure including a first bonding layer, a peripheral circuit layer including a logic circuit, and an interconnection layer; and
a second semiconductor structure including a memory array layer including DRAM memory cells and a second bonding layer; the second bonding layer being bonded to the first bonding layer;
wherein the first semiconductor structure further includes: a first interconnection structure between the logic circuit and the first bonding layer; a contact structure penetrating through a semiconductor layer where the logic circuit is located; and a second interconnection structure and a pad in the interconnection layer; and the logic circuit is connected to the pad through the first interconnection structure, the contact structure, and the second interconnection structure; and
a memory controller connected to the semiconductor device and configured to control the semiconductor device.

11. The memory system of claim 10, wherein the first interconnection structure includes a plurality of first connection structures extending along a first direction and at least one first metal layer extending along at least one of a second direction or a third direction; the at least one first metal layer and the plurality of first connection structures are alternately arranged along the first direction; the first direction is a stacking direction of the first semiconductor structure and the second semiconductor structure; and the second direction intersects with the third direction, and the second direction and the third direction are both perpendicular to the first direction.

12. The memory system of claim 11, wherein the logic circuit includes a decoding circuit, a driving circuit, a sensing amplification circuit, and a row hammer refresh circuit; and the first interconnection structure includes a plurality of the at least one first metal layer; and
wherein the decoding circuit, the driving circuit, the sensing amplification circuit, and the row hammer refresh circuit are respectively connected to a different one of the at least one first metal layer.

13. The memory system of claim 11, wherein the second interconnection structure includes a plurality of second connection structures extending along the first direction and at least one second metal layer extending along at least one of the second direction or the third direction; and the at least one second metal layer and the plurality of second connection structures are alternately arranged along the first direction.

14. A manufacturing method of a semiconductor device, the manufacturing method comprising:
forming a first semiconductor structure including a first bonding layer, a peripheral circuit layer including a logic circuit, and an interconnection layer;
forming a second semiconductor structure including a memory array layer including DRAM memory cells and a second bonding layer; and
bonding the first bonding layer to the second bonding layer;
wherein the method further includes: forming a first interconnection structure between the first bonding layer and the logic circuit; forming a contact structure penetrating through a semiconductor layer where the logic circuit is located; and forming a second interconnection structure and a pad in the interconnection layer, and connecting the logic circuit to the pad through the first interconnection structure, the contact structure, and the second interconnection structure.

15. The manufacturing method of claim 14, wherein the forming the first interconnection structure between the first bonding layer and the logic circuit includes:
forming, between the first bonding layer and the logic circuit, a first connection structure extending along a first direction and at least one first metal layer extending along at least one of a second direction or a third direction, and alternately arranging the at least one first metal layer and a plurality of first connection structures along the first direction; the first direction is a stacking direction of the first semiconductor structure and the second semiconductor structure; and the second direction intersects with the third direction, and the second direction and the third direction are both perpendicular to the first direction.

16. The manufacturing method of claim 15, further including:
forming a decoding circuit, a driving circuit, a sensing amplification circuit and a row hammer refresh circuit in the peripheral circuit layer to form the logic circuit; and
forming a plurality of the at least one first metal layer, and connecting the decoding circuit, the driving circuit, the sensing amplification circuit and the row hammer refresh circuit to different one of the at least one first metal layer respectively.

17. The manufacturing method of claim 15, wherein the forming the second interconnection structure in the interconnection layer includes:
forming, in the interconnection layer, a plurality of second connection structures extending along the first direction and at least one second metal layer extending along at least one of the second direction or the third direction, and alternately arranging the at least one second metal layer and the plurality of second connection structures along the first direction.

18. The manufacturing method of claim 15, wherein the forming the contact structure penetrating through the semiconductor layer where the logic circuit is located includes:
forming a plurality of contact structures penetrating through the semiconductor layer where the logic circuit is located, wherein ones of the plurality of contact structures are arranged at intervals along at least one of the second direction or the third direction.

19. The manufacturing method of claim 18, wherein the forming the contact structure penetrating through the semiconductor layer where the logic circuit is located includes:
forming a via penetrating, along the first direction, through the semiconductor layer where the logic circuit is located;
forming a dielectric layer on a sidewall of the via; and
forming a contact structure in the via where the dielectric layer is formed.

20. The manufacturing method of claim 14, wherein the bonding the second bonding layer to the first bonding layer includes:
forming first bonding contacts and a first insulating layer isolating the first bonding contacts in the first bonding layer;
forming second bonding contacts and a second insulating layer isolating the second bonding contacts in the second bonding layer; and
bonding the first bonding contacts to the second bonding contacts and bonding the first insulating layer to the second insulating layer, to bond the first bonding layer to the second bonding layer.
